(19) United States
(12) Patent Application Publication
(10) Pub. No.: US 2026/0255815 A1
(43) Pub. Date: Aug. 27, 2026

(54) DISPLAY APPARATUS AND TERMINAL DEVICE

(71) Applicants: BEIJING BOE TECHNOLOGY DEVELOPMENT CO., LTD., Beijing (CN); BOE TECHNOLOGY GROUP CO., LTD., Beijing (CN)

(72) Inventors: Haoran WANG, Beijing (CN); Chunyan XIE, Beijing (CN); Song ZHANG, Beijing (CN); Xuekai YANG, Beijing (CN); Linlin XU, Beijing (CN); Xuan TAO, Beijing (CN); Yanli WANG, Beijing (CN)

(21) Appl. No.: 18/992,241

(22) PCT Filed: May 12, 2023
(86) PCT No.: PCT/CN2023/093806

§ 371 Date: Jan. 8, 2025

(51) Int. Cl. H10K 59/131; H10H 29/49; H10H 29/855; H10K 59/80; H10K 102/00

(52) U.S. Cl. CPC H10K 59/131; H10H 29/49; H10H 29/8552; H10K 59/8792; H10K 2102/311

(57) ABSTRACT

A display apparatus and a terminal device are provided. The display apparatus includes a display panel and a drive portion. The display panel includes an inner panel an outer panel, a drive portion, and a connecting portion, wherein the inner panel is provided with a first display area and a first peripheral area; the outer panel surrounds the inner panel and is spaced apart from the inner panel; the outer panel is of an annular structure having a gap; the outer panel is provided with a second display area and a second peripheral area; the outer panel extends towards a backlight side of the inner panel; the drive portion is connected to the first peripheral area and the second peripheral area, for driving the first display area and the second display area to display an image; and the drive portion is a bendable flexible structure.

### TECHNICAL FIELD

The present disclosure relates to the field of display technology, more particularly, to a display apparatus and a terminal device.

### BACKGROUND

At present, terminal devices such as smart watches and smart glasses are more and more widely used, in which a display apparatus is an indispensable component and is used to present a variety of images. The display apparatus in the related art has a limited display area. In order to expand the display area, a display apparatus with a large size is required, but an overall size of the device is also accordingly increased.

It should be noted that information disclosed in this part are provided only for acquiring a better understanding of the background of the present disclosure and therefore may include information that does not constitute the information of the existing art already known to ordinary skilled in the art.

### SUMMARY

The present disclosure provides a display apparatus and a terminal device.

According to an aspect of the present disclosure, there is provided a display apparatus including a display panel and a drive portion. The display panel includes:
an inner panel having a first display area and a first peripheral area located outside the first display area; and
an outer panel surrounding the inner panel and having a clearance with the inner panel, the outer panel being an annular structure having a gap, and the gap cutting off the outer panel; the outer panel has a second display area and a second peripheral area located outside the second display area; and the outer panel extends towards a non-luminous side of the inner panel;
the drive portion is connected to the first peripheral area and the second peripheral area and is configured to drive the first display area and the second display area to display an image; and the drive portion is a bendable flexible structure.

In an exemplary embodiment of the present disclosure, the display panel further includes:
a connection portion connected between the inner panel and the outer panel, the connection portion having a wiring connecting the first peripheral area and the second peripheral area, and the connection portion being a bendable flexible structure;
the drive portion is connected to the second peripheral area of the outer panel, and is connected to the first peripheral area through the second peripheral area and the connection portion.

In an exemplary embodiment of the present disclosure, the drive portion, the connection portion, and the gap are arranged along a straight line passing through a center of the inner panel.

In an exemplary embodiment of the present disclosure, the drive portion, the connection portion, and the gap are arranged along a circumferential direction of the inner panel; and at most two of the drive portion, the connection portion, and the gap are arranged along a straight line passing through a center of the inner panel.

In an exemplary embodiment of the present disclosure, at least one of the connection portion and the drive portion is provided with an opening.

In an exemplary embodiment of the present disclosure, the connection portion and the drive portion are both provided with a plurality of openings;
the openings in one of the connection portion and the drive portion are divided into a plurality of opening groups arranged along a first direction; one of the opening groups includes a plurality of the openings spaced apart along a second direction intersecting with the first direction; in adjacent opening groups, an opening of one opening group corresponds to an area between two adjacent openings of the other opening group.

In an exemplary embodiment of the present disclosure, a shape of the opening is a circle, an ellipse, a polygon, and a waist circle.

In an exemplary embodiment of the present disclosure, a maximum dimension of the opening is not less than 0.005 mm and not greater than 2 mm.

In an exemplary embodiment of the present disclosure, the connection portion is bent towards the non-luminous side of the inner panel, and the drive portion is bent towards a non-luminous side of the outer panel and extends to the non-luminous side of the inner panel.

In an exemplary embodiment of the present disclosure, the drive portion includes a first bent portion, a first extension portion, a second bent portion, and a second extension portion; the first bent portion connects the outer panel and the first extension portion, and the second bent portion connects the first extension portion and the second extension portion;
the first bent portion is bent towards the non-luminous side of the outer panel; the first extension portion extends along an extension direction of the outer panel; the second bent portion is bent in a same direction as the connection portion; and the second extension portion extends along an extension direction of the inner panel.

In an exemplary embodiment of the present disclosure, a gasket is provided at least one of between the second extension portion and the inner panel and between the first extension portion and the outer panel.

In an exemplary embodiment of the present disclosure, an angle between connection lines of two ends of the gap with a center of the inner panel is not greater than 30°; and/or
the gap has a width of not greater than 8 mm.

In an exemplary embodiment of the present disclosure, the drive portion includes a first sub-drive portion and a second sub-drive portion independent of each other; the first sub-drive portion is connected to the first peripheral area; and the second sub-drive portion is connected to the second peripheral area.

In an exemplary embodiment of the present disclosure, the first sub-drive portion includes a first bent portion and a first extension portion; the first bent portion connects the inner panel and the first extension portion; the first bent portion is bent towards the non-luminous side of the inner panel; and the first extension portion extends along an extension direction of the inner panel;
the second sub-drive portion includes a second bent portion and a second extension portion; the second bent portion connects the outer panel and the second extension portion; the second bent portion is bent towards a non-luminous side of the outer panel; and the second extension portion extends along an extension direction of the outer panel.

In an exemplary embodiment of the present disclosure, a gasket is provided at least one of between the first extension portion and the inner panel and between the second extension portion and the outer panel.

In an exemplary embodiment of the present disclosure, the display apparatus further includes:
a transparent cover plate disposed on a light-exiting side of the display panel, the transparent cover plate including a central portion, a transition portion surrounding the central portion, and an edge portion surrounding the transition portion;
the central portion covers the inner panel; the transition portion covers an area between the inner panel and the outer panel and is bent towards a non-luminous side of the display panel; and the edge portion covers the outer panel, and an edge of the outer panel is located inside an edge of the edge portion.

In an exemplary embodiment of the present disclosure, the display apparatus further includes:
a light-absorbing layer at least partially disposed between the transparent cover plate and the display panel. The light-absorbing layer includes a first light-absorbing portion and a second light-absorbing portion surrounding the first light-absorbing portion; the first light-absorbing portion covers the area between the inner panel and the outer panel; and an orthographic projection of the second light-absorbing portion on the transparent cover plate extends to a direction close to the first light-absorbing portion along an edge of the transparent cover plate.

In an exemplary embodiment of the present disclosure, the light-absorbing layer further includes a third light-absorbing portion, and the third light-absorbing portion covers the gap.

In an exemplary embodiment of the present disclosure, the light-absorbing layer further includes a fourth light-absorbing portion disposed on an outer peripheral surface of the transparent cover plate.

In an exemplary embodiment of the present disclosure, the display panel is a flexible structure, and the drive portion and the display panel are an integral structure.

In an exemplary embodiment of the present disclosure, the drive portion is a flexible circuit board connected to the display panel.

According to another aspect of the present disclosure, there is provided a terminal device, including the display apparatus according to any one of the above embodiments.

It should be understood that both the foregoing general description and the following detailed description are only exemplary and explanatory and are not restrictive of the present disclosure.

### BRIEF DESCRIPTION OF THE DRAWINGS

The accompanying drawings, which are incorporated in and constitute part of the description, illustrate the embodiments consistent with the present disclosure and serve to explain the principles of the present disclosure, together with the description. It will be readily apparent to the ordinary skilled person in the art that other embodiments may be made without departing from the spirit and scope of the present disclosure based on these drawings, without need for any creative effort.

FIG. 1 is a schematic view of a display panel in a deformed state in an embodiment of a display apparatus according to the present disclosure.

FIG. 2 is a schematic view of a first display panel in an unfolded state in a first embodiment of a display apparatus according to the present disclosure.

FIG. 3 is an A-A sectional view of the display apparatus of FIG. 2 in a deformed state.

FIG. 4 is a B-B sectional view of the display apparatus of FIG. 2 in the deformed state.

FIG. 5 is a schematic view of a second display panel in an unfolded state in the first embodiment of the display apparatus according to the present disclosure.

FIG. 6 is a C-C sectional view of the display apparatus of FIG. 5 in a deformed state.

FIG. 7 is a D-D sectional view of the display apparatus in FIG. 5 in the deformed state.

FIG. 8 is a schematic view of a fourth light-absorbing portion in an embodiment of a display apparatus according to the present disclosure.

FIG. 9 is a schematic view of openings of a drive portion and a connection portion in an embodiment of a display apparatus according to the present disclosure.

FIG. 10 is a schematic view of first openings of a drive portion and a connection portion in an embodiment of a display apparatus according to the present disclosure.

FIG. 11 is a schematic view of second openings of a drive portion and a connection portion in an embodiment of a display apparatus according to the present disclosure.

FIG. 12 is a schematic view of third openings of a drive portion and a connection portion in an embodiment of a display apparatus according to the present disclosure.

FIG. 13 is a schematic view of fourth openings of a drive portion and a connection portion in an embodiment of a display apparatus according to the present disclosure.

FIG. 14 is a schematic view of fifth openings of a drive portion and a connection portion in an embodiment of a display apparatus according to the present disclosure.

FIG. 15 is a top view of a light-absorbing layer of the display apparatus of FIG. 2 in a deformed state.

FIG. 16 is a schematic view of a third display panel in an unfolded state in the first embodiment of the display apparatus according to the present disclosure.

FIG. 17 is a schematic view of the third display panel in a deformed state in the first embodiment of the display apparatus according to the present disclosure.

FIG. 18 is a schematic view of a light-absorbing layer of the display apparatus of FIG. 17 in a deformed state.

FIG. 19 is a schematic view of a display panel in an unfolded state in a second embodiment of a display apparatus according to the present disclosure.

FIG. 20 is an E-E sectional view of the display apparatus of FIG. 19 in a deformed state.

FIG. 21 is an F-F sectional view of the display apparatus of FIG. 19 in the deformed state.

### DETAILED DESCRIPTION

Now, the exemplary embodiments will be described more comprehensively with reference to the accompanying drawings. However, the exemplary embodiments may be implemented in various forms and should not be construed as limiting to the embodiments herein. Rather, the embodiments are provided to make the present disclosure comprehensive and through and to fully convey the concept of the exemplary embodiments to the ordinary skilled person in the art. The same reference numbers in the drawings indicate the same or similar structures, and thus detailed descriptions thereof will be omitted. In addition, the drawings are merely schematic illustrations of the present disclosure and are not necessarily drawn to scale.

The terms “a”, “an”, “the”, “said” and “at least one”, are used to express the presence of one or more the element/constitute/or the like. The terms “comprise”, “include” and “have” are intended to be inclusive, and mean there may be additional elements/constituents/or the like other than the listed elements/constituents/or the like. The “first” and “second” are used only as marks and are not numerical restriction to the objects.

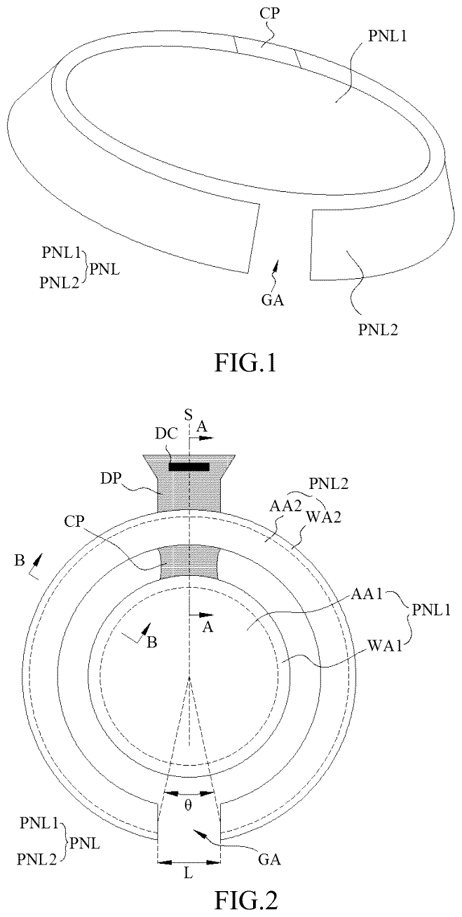

As shown in FIG. 1 and FIG. 2, a display apparatus may include a display panel PNL and a drive portion DP, and the display panel PNL may include an inner panel PNL1, an outer panel PNL2, and the drive portion DP.

The inner panel PNL1 has a first display area AA1 and a first peripheral area WA1 located outside the first display area AA1.

The outer panel PNL2 surrounds the inner panel PNL1 and has a clearance with the inner panel PNL1. The outer panel PNL2 is of an annular structure having a gap GA, and the gap GA cuts off the outer panel PNL2. The outer panel PNL2 has a second display area AA2 and a second peripheral area WA2 located outside the second display area AA2. The outer panel PNL2 extends towards a non-luminous side of the inner panel PNL1.

The drive portion DP is connected to the first peripheral area WA1 and the second peripheral area WA2, and is configured to drive the first display area AA1 and the second display area AA2 to display an image. The drive portion DP is a bendable flexible structure.

The display apparatus according to the embodiments of the present disclosure adopts two panels (inner and outer panels) to realize display, and the outer panel PNL2 extends towards the non-luminous side of the inner panel PNL1, so that the outer panel PNL2 is a slope extending towards the non-luminous side. The inner panel PNL1 is used as a main display area, and the outer panel PNL2 corresponds to an edge area of the display apparatus and is used as an auxiliary display area, which enables the edge area that originally does not emit light to display an image as well when being applied to a terminal device, thereby improving a display area without increasing an overall size. The drive portion DP and the first peripheral area WA1 may drive the first display area AA1 to emit light, and the drive portion DP and the second peripheral area WA2 may drive the second display area AA2 to emit light. Meanwhile, the drive portion DP may be bent to the non-luminous side of the inner panel PNL1 to reduce space occupied by the drive portion DP in the edge area, which facilitate improving a screen-to-body ratio.

The display apparatus according to the present disclosure will be described in detail below.

As shown in FIG. 2, the display apparatus may include the display panel PNL and the drive portion DP connected to each other, and the display panel PNL may be driven by the drive portion DP to display an image.

The display panel PNL has a plurality of light-emitting devices, and the light-emitting devices may be OLEDs (organic light-emitting diodes) made of organic light-emitting materials, or may be LEDs (light-emitting diodes) made of inorganic light-emitting materials, such as Micro LEDs (micro light-emitting diodes) and Mini LEDs (sub-millimeter light-emitting diodes), or the light-emitting devices may also be devices such as QLEDs (quantum dot light-emitting diodes).

The display panel PNL may include a drive backplane and a light-emitting device located on a side of the drive backplane. A light-exiting side of the display panel PNL may be a side from which light is emitted, i.e., a side of the light-emitting device away from the drive backplane; and a non-luminous side of the display panel PNL may be a side opposite to a light-exiting direction, i.e., a side of the drive backplane away from the light-emitting device.

The drive backplane has a drive circuit capable of driving the light-emitting device to emit light to display an image.

For example, the drive backplane may include a substrate and a circuit layer located on a side of the substrate. The substrate may be a flat plate structure, and a material thereof may be a hard material such as glass or may be a soft material such as polyimide. Meanwhile, the substrate may be a single-layer or multi-layer structure. The circuit layer may be disposed on one side of the substrate.

The circuit layer may include the drive circuit, and the drive circuit may drive the light-emitting device to emit light. The drive circuit may include a pixel circuit and a peripheral circuit. The pixel circuit may be for example 7T1C pixel circuit or 3T1C pixel circuit, as long as it can drive the light-emitting device to emit light, the structure of which is not particularly limited herein. “nTmC” indicates that a pixel circuit includes n transistors (denoted by a letter “T”) and m capacitors (denoted by a letter “C”). The number of the pixel circuits may be identical to the number of the light-emitting devices, and the pixel circuits are connected to the light-emitting devices in one-to-one correspondence, so as to respectively control the light-emitting devices to emit light. Certainly, the number of the pixel circuits may be less than the number of the light-emitting devices; for example, one pixel circuit may be connected to a plurality of light-emitting devices and simultaneously drive the plurality of light-emitting devices to emit light, which is not specifically limited herein. Alternatively, the number of the pixel circuits may be more than the number of the light-emitting devices, and there may be a dummy pixel circuit that is not connected to any light-emitting device and may be arranged in an area with no light-emitting device, which is beneficial for improving uniformity of the circuit layer.

The peripheral circuit is connected to the pixel circuit and is used to input a drive signal to the pixel circuit, so as to control the light-emitting device to emit light. The peripheral circuit may include a gate drive circuit, and may further include a light-emitting control circuit or the like, which depends on the composition of the pixel circuit. The peripheral circuit may include a thin film transistor and a capacitor, and the specific structure of the peripheral circuit is not particularly limited herein.

The above circuit layer may include a plurality of thin film transistors and capacitors. The thin film transistors may be top-gate or bottom-gate thin film transistors. Each thin film transistor may include an active layer and a gate. Active layers of the thin film transistors are disposed in a same semiconductor layer, and gates thereof may be disposed in a same gate layer, so as to simplify the process.

The light-emitting device may include a first electrode and a second electrode, as well as a light-emitting layer located between the first electrode and the second electrode. The light-emitting layer may be excited to emit light by applying an electrical signal to the first electrode and the second electrode. Meanwhile, in order to prevent crosstalk and limit the position of the light-emitting device, the display panel PNL may further include a pixel defining layer, which may be disposed along with the light-emitting device on one side of the drive backplane, for example, a surface of the circuit layer away from the substrate.

First electrodes of the light-emitting devices are spaced apart, and the pixel defining layer is provided with pixel openings exposing the first electrodes, that is, one pixel opening exposes one first electrode. A range corresponding to one pixel opening is a range of one light-emitting device. The light-emitting layer is at least partially located in the pixel opening and is stacked with the first electrode. Light-emitting layers of individual light-emitting devices may form a continuous whole layer structure; alternatively, the light-emitting layers of different light-emitting devices may be spaced apart from each other.

The second electrode may cover the light-emitting layer, and the second electrode may be a continuous whole layer structure, so that individual light-emitting devices may share a common second electrode. The second electrode may be a cathode of the light-emitting devices, and may adopt a light-transmitting structure, so that the light-emitting devices may emit light in a direction away from the drive backplane.

In addition, the display panel PNL may further include an encapsulation layer that may cover each light-emitting device and that is configured to block external water and oxygen and prevent them from eroding the light-emitting device. For example, the encapsulation layer may adopt a thin film encapsulation method, and may include a first inorganic layer, an organic layer, and a second inorganic layer.

The first inorganic layer may cover each light-emitting device. The organic layer may be disposed on a surface of the first inorganic layer away from the drive backplane, and a boundary of the organic layer may be defined inside a boundary of the first inorganic layer by a barrier dam or another structure surrounding the light-emitting device. The second inorganic layer may cover the organic layer and the first inorganic layer that is not covered by the organic layer; water and oxygen intrusion may be blocked by the second inorganic layer; and planarization is achieved by the organic layer having fluidity before curing. Materials of the first inorganic layer and the second inorganic layer may include inorganic insulating materials such as silicon nitride and silicon oxide.

In some embodiments of the present disclosure, the display apparatus according to the present disclosure may further include a functional layer FL, and the functional layer FL may be disposed on a side of the encapsulation layer away from the drive backplane. The functional layer FL may include a touch layer configured to sense a touch operation, and the touch layer may adopt a touch structure such as self-capacitance, mutual capacitance or resistance, which is not particularly limited herein. Certainly, the functional layer FL may not include any touch layer.

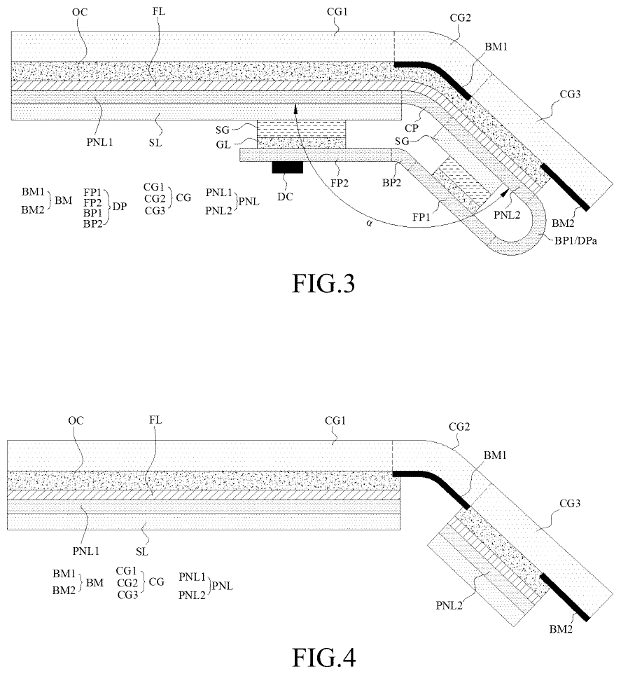

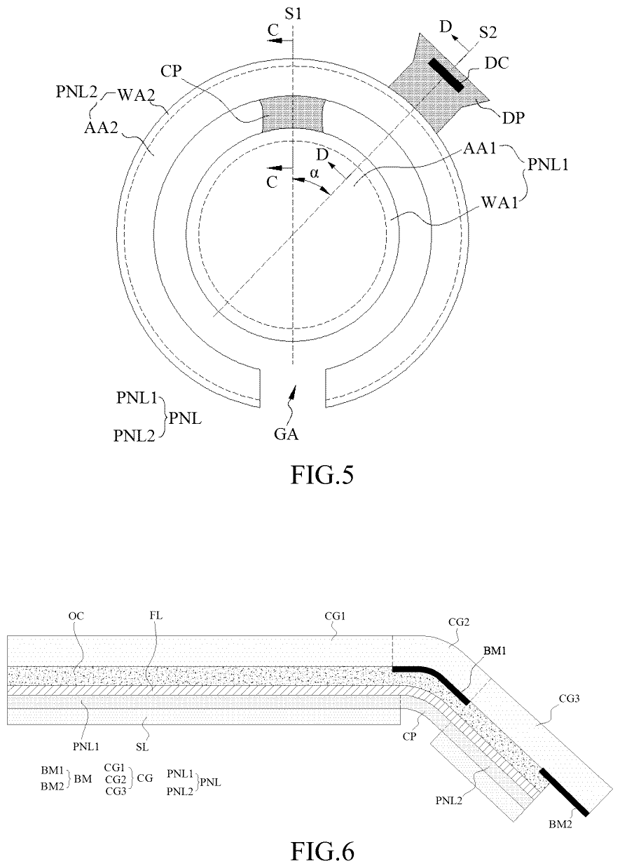

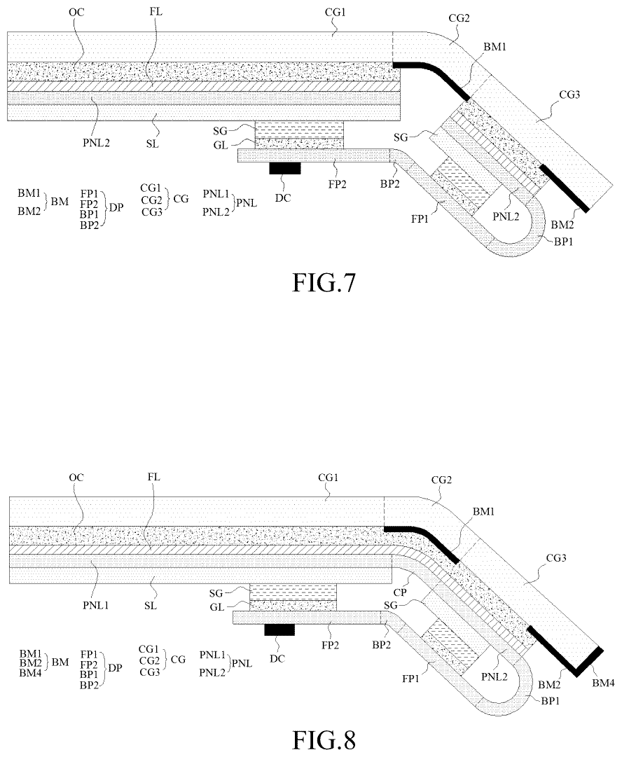

As shown in FIG. 3 and FIG. 4, the functional layer FL may further include a color film layer having a plurality of filter portions. For the light-emitting layer of the whole layer structure, color display may be achieved through a filtering effect of the filter portions. For the light-emitting layers that are spaced apart, the color film layer can filter out ambient light and play a role in reducing reflection. Certainly, for the light-emitting layers that are spaced apart, the color film layer may be replaced with a circular polarizer.

As shown in FIG. 3 and FIG. 4, in some embodiments of the present disclosure, the display apparatus according to the present disclosure may further include a transparent cover plate CG, which may be made of glass or other transparent materials, and which may be disposed on a side of the functional layer FL away from the display panel PNL. For example, the transparent cover plate CG may be bonded to a surface of the functional layer FL away from the display panel PNL through a bonding layer OC.

As shown in FIG. 3 and FIG. 4, in some embodiments of the present disclosure, the display panel PNL may further include a buffer heat dissipation layer SL, which may be disposed on a backlight surface of the display panel PNL, i.e., a surface of the drive backplane away from the light-emitting device. The buffer heat dissipation layer SL may include a back film and a support layer, and the back film may be attached to the surface of the drive backplane away from the light-emitting device. The support layer may be attached to a surface of the back film away from the light-emitting device. The support layer may include an adhesive layer, a buffer layer, and a heat dissipation layer stacked in a direction away from the display panel PNL. The adhesive layer may be made of a mesh adhesive or the like; the buffer layer may be made of foam or other materials; the heat dissipation layer may be made of copper or other metal materials with good thermal conductivity, and the heat dissipation layer made of a metal material may also play a role in improving strength. In addition, the display panel PNL may not be provided with any back film, and instead the heat dissipation layer is directly disposed on the surface of the drive backplane away from the light-emitting device.

As shown in FIG. 2, the display panel PNL of the present disclosure may be at least divided into an inner panel PNL1 and an outer panel PNL2 independent of each other, and both the inner panel PNL1 and the outer panel PNL2 have the light-emitting device and the drive circuit described above.

A light-exiting side of the inner panel PNL1 and a light-exiting side of the outer panel PNL2 are the light-exiting side of the display panel PNL; and a non-luminous side of the inner panel PNL1 and a non-luminous side of the outer panel PNL2 are the non-luminous side of the display panel PNL.

The inner panel PNL1 has a first display area AA1 and a first peripheral area WA1 located outside the first display area AA1, and the first peripheral area WA1 may be a closed or unclosed annular area surrounding the first display area AA1. The first display area AA1 has a light-emitting device and a pixel circuit connected to the light-emitting device, i.e., a first light-emitting device and a first pixel circuit. The first peripheral area WA1 has a peripheral circuit, i.e., a first peripheral circuit. A control signal may be output to the first pixel circuit through the first peripheral circuit, to control the light-emitting timing and gray scale of the first light-emitting device, so as to cause the inner panel PNL1 to display an image.

As shown in FIG. 2, the outer panel PNL2 may surround the inner panel PNL1 with a clearance therebetween, that is, the inner panel PNL1 is not in direct contact with the outer panel PNL2. The outer panel PNL2 may be an annular structure and has a gap GA that cuts off the outer panel PNL2 in a radial direction of the inner panel PNL1, so that the outer panel PNL2 is not closed in a circumferential direction. The clearance between the inner panel PNL1 and the outer panel PNL2 may be formed by cutting off the same display panel PNL. Certainly, the inner panel PNL1 and the outer panel PNL2 may also be manufactured separately.

As shown in FIGS. 1-4, the outer panel PNL2 may be a flexible panel and may extend towards the non-luminous side of the inner panel PNL1, so that the outer panel PNL2 is a slope extending towards the non-luminous side of the inner panel PNL1, and an angle a between the outer panel PNL2 and the inner panel PNL1 may be an obtuse angle, in which case the display panel PNL is in a deformed state. In an unfolded state, the outer panel PNL2 and the inner panel PNL1 may be arranged along a same plane; by deforming the outer panel PNL2, the foregoing slope may be formed, and the gap GA may gradually decrease in a process of forming the slope. That is, the unfolded state is a state in which the outer panel PNL2 has not formed the slope, and the deformed state is a state in which the outer pane is bent to form the slope. In a process of conversion from the unfolded state to the deformed state, due to the existence of the gap GA, a circumferential dimension of the outer panel PNL2 is reduced, that is, the gap GA can provide space for the contraction of the outer panel PNL2 during deformation; if the outer panel PNL2 is of a completely closed annular structure, wrinkles are inevitably present during bending, and the gap GA can avoid wrinkling. When the display panel PNL of the present disclosure may be in the deformed state when applied to the terminal device. The unfolded state may exist during manufacturing, assembling and other processes before leaving the factory.

The outer panel PNL2 has a second display area AA2 and a second peripheral area WA2 located outside the second display area AA2. The second peripheral area WA2 and the second display area AA2 may be annular areas concentrically surrounding the inner panel PNL1. Corresponding to the shape of the outer panel PNL2, the second display area AA2 and the second peripheral area WA2 are also discontinuous at the gap GA. The second display area AA2 has a light-emitting device and a pixel circuit connected to the light-emitting device, i.e., a first light-emitting device and a first pixel circuit. The second peripheral area WA2 has a peripheral circuit, i.e., a second peripheral circuit. A control signal may be output to the second pixel circuit through the second peripheral circuit, to control the light-emitting timing and gray scale of the second light-emitting device, so as to cause the outer panel PNL2 to display an image.

As shown in FIG. 1 and FIG. 2, in some embodiments of the present disclosure, an outline of the inner panel PNL1 is a circle, an outline of the outer panel PNL2 is an unclosed annulus, and a shape of the display panel PNL formed by the slope-like outer panel PNL2 and the inner panel PNL1 may be a circular truncated cone.

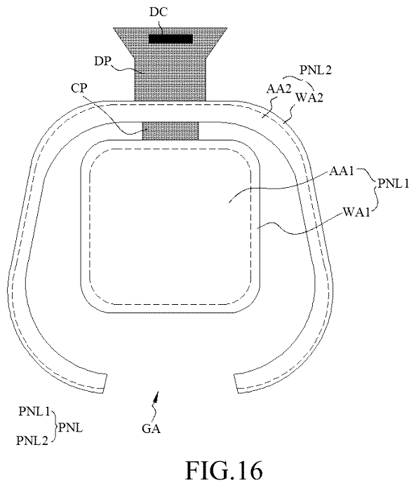

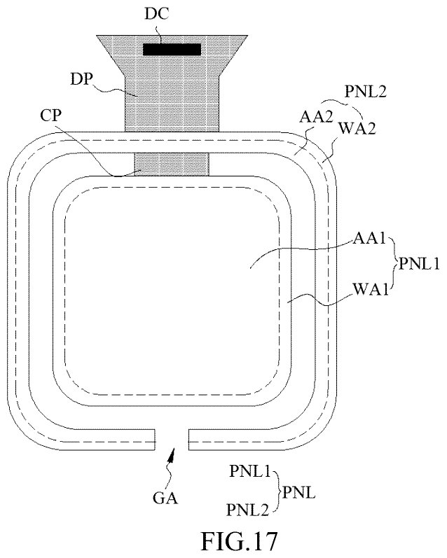

As shown in FIG. 16 and FIG. 17, in some embodiments of the present disclosure, the outline of the inner panel PNL1 may be a rectangle or other polygons, the outline of the outer panel PNL2 is an unclosed polygonal annulus structure, and the shape of the display panel PNL formed by the slope-like outer panel PNL2 and the inner panel PNL1 may be a frustum. FIG. 16 is a top view of the unfolded state, and FIG. 17 is a top view of the deformed state. Certainly, the aforementioned polygons including corners may adopt a manner of transition by rounded corners.

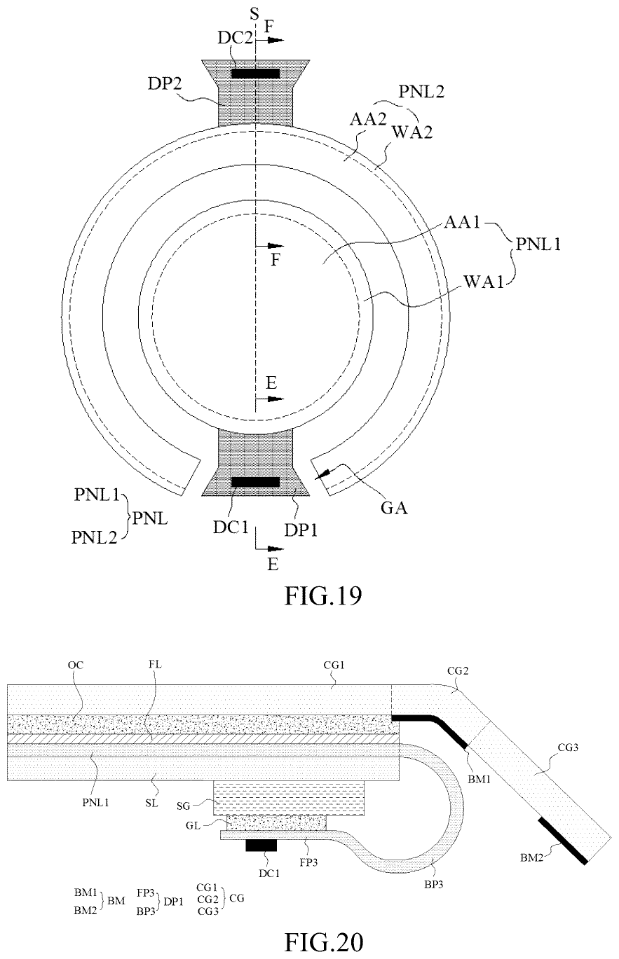

As shown in FIG. 2, FIG. 5 and FIG. 19, the drive portion DP may be provided with a drive chip DC, and the peripheral circuit of the display panel PNL may be connected to the drive chip DC, so that the drive chip DC may control the peripheral circuit to output a drive signal to enable the display panel PNL to display an image. The inner display portion and the outer display portion may be controlled by the same drive portion DP and the drive chip DC thereon, in which case the inner panel PNL1 and the outer panel PNL2 need to be connected and then connected to the drive portion DP. Alternatively, the drive portion DP may be divided into two independent sub-drive portions DP, each of the two sub-drive portions DP may be provided with a drive chip DC, and the inner panel PNL1 and the outer panel PNL2 are driven by the two drive portions DP. In such a case, the sub-drive portions DP may drive the inner panel PNL1 and the outer panel PNL2, respectively, and the inner panel PNL1 and the outer panel PNL2 may be disposed in a completely disconnected manner.

As shown in FIG. 4 and FIG. 20, the drive portion DP may be a flexible structure. In the deformed state, the drive portion DP may be bent to the non-luminous side of the display panel PNL, and in the unfolded state, the drive portion DP may extend along an extension direction of the display panel PNL. For example, the drive portion DP and the display panel PNL may bean integral flexible structure, so that the drive portion DP and the display panel PNL may be formed simultaneously, which helps to simplify the structure. Certainly, the drive portion DP may also be a flexible circuit board disposed separately from the display panel PNL, as long as it can be connected to the display panel PNL.

### First Implementation

As shown in FIGS. 2-4, the display panel PNL may include a connection portion CP, which may be connected between the inner panel PNL1 and the outer panel PNL2, and the connection portion CP has a wiring connecting the first peripheral area WA1 and the second peripheral area WA2. Meanwhile, the connection portion CP is a bendable flexible structure, and when the display panel PNL is deformed from the unfolded state to the deformed state, the connection portion CP is correspondingly bent, so that the connection is realized without hindering the change of state.

In some embodiments, the drive portion DP may be connected to the second peripheral area WA2 of the outer panel PNL2, and in the unfolded state, the drive portion DP is connected to a side of the outer panel PNL2 away from the inner panel PNL1 and extends in a direction away from the inner panel PNL1. The drive portion DP may be connected to the first peripheral area WA1 through the second peripheral area WA2 and the connection portion CP, that is, the first peripheral circuit in the first peripheral area WA1 of the inner panel PNL1 may be connected to the drive portion DP through the connection portion CP and the second peripheral area WA2. Specifically, the first peripheral area WA1 and the second peripheral area WA2 may be provided with a wiring for connection with the first peripheral circuit, and the wiring may be connected to the drive chip DC through the wiring in the connection portion CP and a wring in the drive portion DP, thereby forming a path connecting the first peripheral circuit and the drive chip DC. Meanwhile, the second peripheral circuit of the second peripheral area WA2 of the outer panel PNL2 may be directly connected to the drive chip DC through the wiring in the drive portion DP.

The connection portion CP, the inner panel PNL1, and the outer panel PNL2 may be an integral flexible structure, so that the connection portion CP may be formed simultaneously with the display panel PNL, which helps to simplify the structure without need to carry out a special connection process. Certainly, the connection portion CP may also be a flexible circuit board disposed separately from the display panel PNL, as long as it can be used to connect the first peripheral circuit and the drive portion DP.

In some embodiments, as shown in FIG. 2, the connection portion CP and the gap GA may be arranged along a radial straight line, that is, along a straight line S passing through a center of the inner panel PNL1. Meanwhile, the outer panel PNL2 may be symmetrical about the straight line S, that is, the outline of the outer panel PNL2 is an axisymmetric pattern. Since the connection portion CP connects the inner panel PNL1 and the outer panel PNL2, the connection portion CP may be symmetrical about the straight line S, and force on the outer panel PNL2 on both sides of the connection portion CP is balanced.

Further, as shown in FIG. 2, in an embodiment, the drive portion DP, the connection portion CP and the gap GA may be arranged along the radial straight line S, that is, along the straight line S passing through the center of the inner panel PNL1, so that the drive portion DP and the connection portion CP are connected to two sides of a same area of the outer panel PNL2, stress points of the outer panel PNL2 are concentrated, and other areas are less likely to be affected in case of deformation.

Certainly, in other embodiments of the present disclosure, the drive portion DP and the connection portion CP may also be arranged along the circumferential direction of the outer panel PNL2. As shown in FIG. 5, the connection portion CP and the gap GA may be arranged along a straight line S1; the drive portion DP and the center of the inner panel PNL1 may be arranged along a straight line S2; the angle a between the straight line S1 and the straight line S2 is greater than 0° and less than 180°. The drive portion DP may be provided at any position on an outer side of the outer panel PNL2 except at the gap GA, and the specific position of the drive portion DP is not particularly limited herein.

In addition, in some embodiments, since the drive portion DP is located outside the outer panel PNL2, the inner panel PNL1 does not need to be specially provided with the drive portion DP, and the gap GA does not have to be used to avoid the drive portion DP, so that the gap GA can be reduced as much as possible. For example, as shown in FIG. 2, in the unfolded state, an angle θ between connection lines of two ends of the gap GA with the center of the inner panel PNL1 is not greater than 30°, such as 30°, 20°, etc. The angle may be an angle between connection lines of respective centers of the two ends of the gap GA with the center of the inner panel PNL1. In addition, the gap GA may have a width L of not greater than 8 mm, for example, 8 mm, 6 mm, etc., to minimize the loss of the outer panel PNL2 at the gap GA. The width of the gap GA is a distance between two segments. In the deformed state, the two ends of the gap GA may be in contact or have a clearance.

As shown in FIG. 2, in an example where the drive portion DP, the connection portion CP and the gap GA are arranged along the straight line S passing through the center of the inner panel PNL1, the connection portion CP and the drive portion DP may be both bent towards the non-luminous side of the inner panel PNL1. The outer panel PNL2 may extend towards the non-luminous side of the inner panel PNL1 by bending the connection portion CP, and the angle between the outer panel PNL2 and the inner panel PNL1 is an obtuse angle. The drive portion DP may extend to a position corresponding to the inner panel PNL1 by bending the drive portion DP.

As shown in FIG. 3, in the deformed state, the drive portion DP may include a first bent portion BP1, a first extension portion FP1, a second bent portion BP2, and a second extension portion FP2; the first bent portion BP1 connects the outer panel PNL2 and the first extension portion FP1; and the second bent portion BP2 connects the first extension portion FP1 and the second extension portion FP2.

The first bent portion BP1 may be bent towards the non-luminous side of the outer panel PNL2, and the first extension portion FP1 may extend along an extension direction of the outer panel PNL2, so that the first extension portion FP1 may be parallel to the outer panel PNL2. The second bent portion BP2 may be bent in a same direction as the connection portion CP, that is, the second bent portion BP2 and the connection portion CP may be bent around straight lines parallel to each other. Meanwhile, the second extension portion FP2 may extend along an extension direction of the inner panel PNL1, so that the second extension portion FP2 may be disposed parallel to the inner panel PNL1.

Further, as shown in FIG. 3, gaskets SG may be provided between the second extension portion FP2 and the inner panel PNL1 and between the first extension portion FP1 and the outer panel PNL2. For example, a first gasket may be provided between the second extension portion FP2 and the inner panel PNL1, and the first gasket functions to support the second extension portion FP2; the first gasket may be clamped between the buffer heat dissipation layer SL at the second extension portion FP2 and the buffer heat dissipation layer SL at the inner panel PNL1, and may be bonded to the second extension portion FP2 through an adhesive layer GL.

A second gasket may be provided between the first extension portion FP1 and the outer panel PNL2, and the second gasket functions to support the first extension portion FP1; the second gasket may be clamped between the buffer heat dissipation layer SL at the first extension portion FP1 and the buffer heat dissipation layer SL at the outer panel PNL2, and may be bonded to the first extension portion FP1 through another adhesive layer GL.

Certainly, in other embodiments of the present disclosure, the gasket SG may be provided only between the second extension portion FP2 and the inner panel PNL1, or only between the first extension portion FP1 and the outer panel PNL2.

The above gasket SG may be made of metal or alloy materials; certainly, it may be made of non-metal materials, as long as it can play a supporting role.

In addition, as shown in FIG. 3 and FIG. 4, for the above solution in which the drive portion DP, the connection portion CP, and the display panel PNL may be an integrated structure, in order to facilitate bending, the buffer heat dissipation layer SL may be disconnected at an area corresponding to the first bent portion BA1 and the second bent portion BA2, and further, the functional layer FL may be disconnected at an area corresponding to at least one of the first bent portion BA1 and the second bent portion BA2.

As shown in FIG. 3 and FIG. 4, in some embodiments of the present disclosure, when the display panel PNL is in the deformed state, accordingly the transparent cover plate CG may be attached to the display panel PNL. For example, the transparent cover plate CG is bonded to a surface of the functional layer FL away from the drive backplane through the bonding layer OC. The transparent cover plate CG may include a center portion CG1, a transition portion CG2 surrounding the center portion CG1, and an edge portion CG3 surrounding the transition portion CG2.

The central portion CG1 may cover the inner panel PNL1, and a boundary of the central portion CG1 and a boundary of the inner panel PNL1 may be aligned in a direction perpendicular to the inner panel PNL1. The transition portion CG2 may cover an area between the inner panel PNL1 and the outer panel PNL2, and be bent towards the non-luminous side of the display panel PNL. In an area corresponding to the connection portion CP, the transition portion CG2 is conformally attached to and is bent synchronously with the connection portion CP. In an area without the connection portion CP between the inner panel PNL1 and the outer panel PNL2, the transition portion CG2 is not in contact with the display panel PNL. The edge portion CG3 may cover the outer panel PNL2, and may be conformally attached to the outer panel PNL2, or certainly may not be attached to the outer panel PNL2, but an edge of the outer panel PNL2 is located inside an edge of the edge portion CG3, and the outer panel PNL2 does not extend out of the transparent cover plate CG.

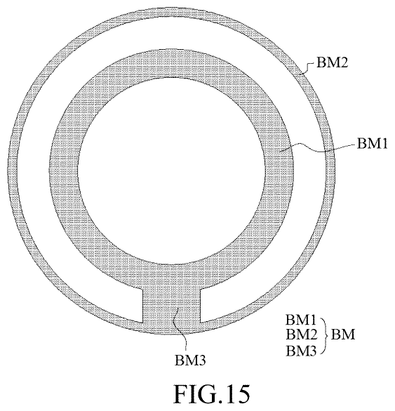

As shown in FIG. 3, FIG. 4 and FIG. 15, in order to shield peripheral areas of the inner panel PNL1 and the outer panel PNL2 as well as areas between the inner panel PNL1 and the outer panel PNL2, which do not emit light, the display apparatus further includes a light-absorbing layer BM, which may be at least partially disposed between the transparent cover plate CG and the display panel PNL. Meanwhile, the light-absorbing layer BM may be made of black resin or other light-absorbing materials, and the light-absorbing layer BM may include a first light-absorbing portion BM1 and a second light-absorbing portion BM2 surrounding the first light-absorbing portion BM1.

The first light-absorbing portion BM1 may cover an area between the inner panel PNL1 and the outer panel PNL2 and may be an annular structure. A distance between an inner boundary and an outer boundary of the first light-absorbing portion BM1 may be greater than a distance between the inner panel PNL1 and the outer panel PNL2, and also greater than a length of the connection portion CP in the radial direction of the inner panel PNL1, so as to ensure that the first light-absorbing portion BM1 can shield the area between the inner panel PNL1 and the outer panel PNL2.

An orthographic projection of the second light-absorbing portion BM2 on the transparent cover plate CG may extend along an edge of the transparent cover plate CG in a direction close to the first light-absorbing portion BM1, but the second light-absorbing portion BM2 is not in contact with the first light-absorbing portion BM1, and the second light-absorbing portion BM2 may also be an annular structure.

At least one of the first light-absorbing portion BM1 and the second light-absorbing portion BM2 may be a continuous annular structure, and may span an area corresponding to the gap GA. Certainly, one or both of the first light-absorbing portion BM1 and the second light-absorbing portion BM2 may be a discontinuous annular structure and disconnected at a position corresponding to the gap GA. Further, in order to shield the gap GA, the light-absorbing layer BM may further include a third light-absorbing portion BM3, which may shield the gap GA and form an integral structure with the first light-absorbing portion BM1 and the second light-absorbing portion BM2.

By matching a range of the first light-absorbing portion BM1 and a range of the second light-absorbing portion BM2 with a range of the first display area AA1 and a range of the second display area AA2, the first display area AA1 is located within the range surrounded by the first light-absorbing portion BM1, and a boundary of the first display area AA1 may be aligned with the inner boundary of the first light-absorbing portion BM1 in the direction perpendicular to the inner panel PNL1; the second display area AA2 may be located between the first light-absorbing portion BM1 and the second light-absorbing portion BM2, an inner boundary of the second display area AA2 may be aligned with the outer boundary of the first light-absorbing portion BM1 in a direction perpendicular to the outer panel PNL2, and an outer boundary of the second display area AA2 may be aligned with an inner boundary of the second light-absorbing portion BM2 in the direction perpendicular to the outer panel PNL2.

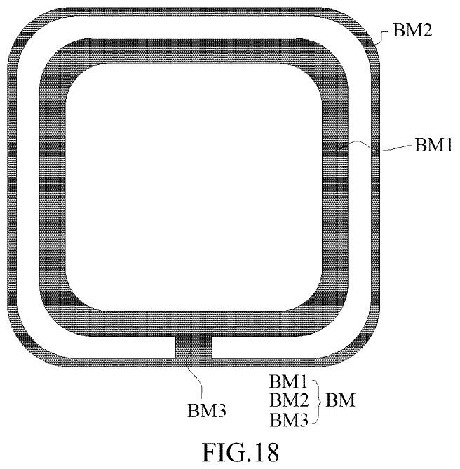

As shown in FIG. 3, FIG. 4 and FIG. 15, based on the light-absorbing layer BM described above, in terms of visual effect, two black annular structures can be seen on the display apparatus, an area corresponding to the second light-absorbing portion BM2 is at the periphery, and an area corresponding to the first light-absorbing portion BM1 is inside. FIG. 15 is a top view of the light-absorbing layer BM of the display apparatus of FIG. 2 in the deformed state, that is, a top view of the light-absorbing layer BM of the display apparatus in FIG. 3 and FIG. 4. Meanwhile, referring to FIG. 18, which is a top view of the light-absorbing layer BM of the display apparatus in FIG. 17, it can be seen that, in terms of visual effect, two black annular structures can be seen on the display apparatus, an area corresponding to the second light-absorbing portion BM2 is at the periphery while an area corresponding to the first light-absorbing portion BM1 is inside, and the annular structure is not a circular ring, but a square ring with rounded corners.

In some embodiments, the light-absorbing layer BM may be disposed on a surface of the transparent cover plate CG close to the display panel PNL, and the first light-absorbing portion BM1 may be conformally attached to the transition portion of the transparent cover plate CG.

As shown in FIG. 8, in some embodiments, the light-absorbing layer BM may further include a fourth light-absorbing portion BM4, which may be disposed on an outer peripheral surface of the transparent cover plate CG and may absorb edge leakage light, and the fourth light-absorbing portion BM4 and the second light-absorbing portion BM2 may be an integral structure.

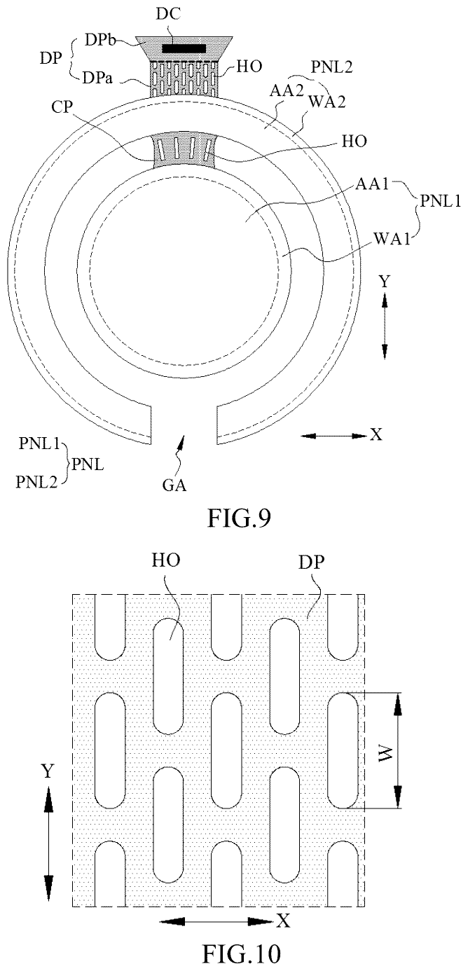

As shown in FIG. 9, in order to reduce resistance from the unfolded state to the deformed state, at least one of the connection portion CP and the drive portion DP may be provided with an opening HO, through which the flexibility is improved and the bending is facilitated. The opening HO may be a through hole penetrating the connection portion CP and the drive portion DP, or may be a blind hole that does not penetrate, as long as it can improve the flexibility and facilitate for the deformation.

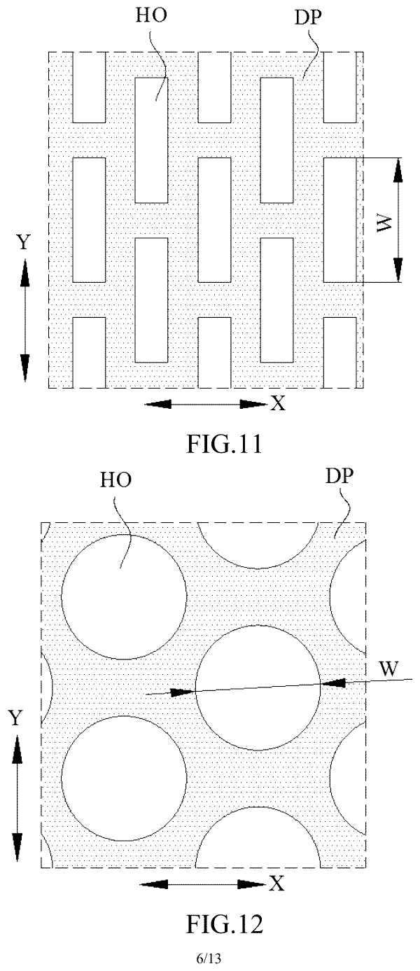

The shape of the opening HO is not particularly limited herein; for example, the opening HO may be in the shape of a circle (as shown in FIG. 12), an ellipse, an arc, a polygon, and a waist circle (as shown in FIG. 10), and the polygon may be a rectangle (as shown in FIG. 11), a diamond, or the like. Certainly, other shapes may be used. If a shape having a curved area, such as a circle, an ellipse, or a waist circle, is used, sharp edges can be reduced or avoided, which helps to prevent stress concentration and reduce a risk of breakage of the connection portion CP and the drive portion DP.

As shown in FIGS. 10-12, in some embodiments of the present disclosure. The connection portion CP and the drive portion DP are both provided with a plurality of openings HO. Taking one of the connection portion CP and the drive portion DP as an example: individual openings HO may be divided into a plurality of opening groups arranged along a first direction X, and each opening group may include a plurality of openings HO spaced apart along a second direction Y. The first direction X and the second direction Y are mutually intersecting directions; for example, the first direction X is perpendicular to the second direction Y. Further, the drive portion DP, the connection portion CP, and the gap GA may be arranged along a straight line extending in the second direction Y. As a result, it is advantageous to design a path of the wirings in the connection portion CP and the drive portion DP, and the wirings may pass through an area between two opening groups without need to have more curved portions to avoid the openings HO.

As shown in FIG. 10 to FIG. 12, in two adjacent opening groups in the first direction X, any opening HO of one opening group corresponds to an area between two adjacent openings HO of the other opening group. That is, openings HO of two adjacent opening groups are staggered, so that a distance between two adjacent openings HO (with no other opening HO between the two openings HO) arranged along a same straight line in the first direction X is enlarged, which helps to improve strength of the connection portion CP and the drive portion DP to make them less prone to breakage due to bending while satisfying the flexibility requirement.

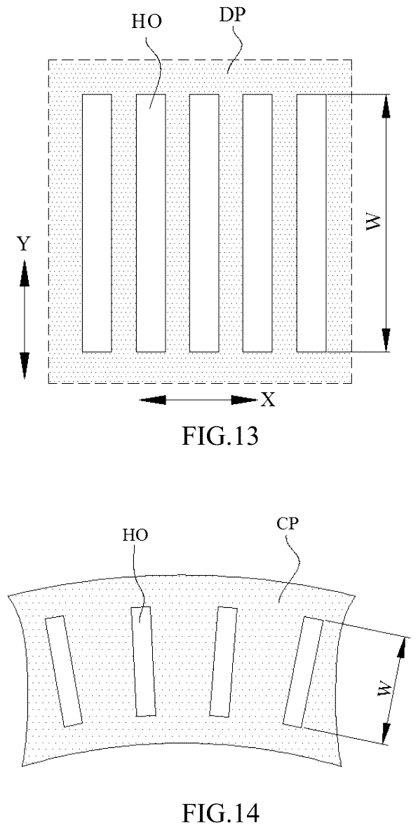

As shown in FIG. 9 and FIG. 10, in an embodiment, the opening HO is in the shape of a waist circle, and the above-mentioned staggered arrangement may be adopted, which can not only avoid stress concentration, but also reduce the breakage risk. In other embodiments of the present disclosure, the connection portion CP and the drive portion DP are both provided with a plurality of openings HO, and the openings are in one of the connection portion CP and the drive portion DP. As shown in FIG. 11 and FIG. 12, the openings HO may also be arranged in a rectangular or circular array. Alternatively, the openings HO may be arranged along a straight line extending in the first direction X (as shown in FIG. 13) or extending in the second direction Y. Alternatively, if the openings HO are arc-shaped, the plurality of openings HO may be concentrically arranged around the inner panel PNL1 in a direction away from the inner panel PNL1. In addition, as shown in FIG. 9 and FIG. 14, the openings HO may be rectangular and may be radially arranged around the inner panel PNL1. Certainly, other distribution manners may also be used, which will not be enumerated herein.

The shapes and arrangements of the openings HO described above may be combined in various ways, and the openings HO of the connection portion CP and the drive portion DP may have different shapes and may have different arrangements.

Further, in some embodiments, as shown in FIG. 3 and FIG. 9, the drive portion DP may include an opening area DPa and a non-opening area DPb. The openings HO of the drive portion DP are in the opening area DPa, and the non-opening area DPb may not be provided with any openings HO. The drive chip DC may be disposed in the non-opening area DPb.

In some embodiments of the present disclosure, as shown in FIGS. 10-14, a maximum dimension W of the opening HO is not less than 0.005 mm and not greater than 2 mm, for example, 0.005 mm, 0.015 mm, 0.1 mm, 1 mm, and 2 mm. The maximum dimension may be a distance between two points that are farthest away from each other in an outline of the opening HO. For example, as shown in FIG. 10, the opening HO is in the shape of a waist circle, and the maximum dimension W is a length of the waist circle; as shown in FIG. 11 and FIG. 13, the opening HO is in the shape of a rectangle, and the maximum dimension W is a length of the rectangle; as shown in FIG. 12, the opening HO is in the shape of a circle, and the maximum dimension W is a diameter of the circle.

In some embodiments of the present disclosure, in the deformed state, a radius of curvature of the connection portion CP is not less than 0.5 mm and not greater than 5 mm, for example, 0.5 mm, 1.5 mm, 2.5 mm, 3.5 mm, and 5 mm. A radius of curvature of the opening area DPa is not less than 0.1 mm and not greater than 2 mm, for example, 0.1 mm, 0.5 mm, 1 mm, 1.5 mm, and 2 mm, which is not specifically limited herein.

### Second Implementation

As shown in FIG. 19 and FIG. 20, the inner panel PNL1 and the outer panel PNL2 of the display panel PNL may be driven separately and may be completely disconnected rather than connected through the connection portion CP describe above. The flexible structure of the outer panel PNL2 may extend towards the non-luminous side of the inner panel PNL1, and form a circular truncated cone or a prismatic frustum structure together with the inner panel PNL1, at which time the display panel PNL is in the deformed state; in the unfolded state, the outer panel PNL2 extends along the same plane as the inner panel PNL1.

As shown in FIG. 19, the drive portion DP may include a first sub-drive portion DP1 and a second sub-drive portion DP2 that are independent of each other.

The first sub-drive portion DP1 may be connected to the first peripheral area WA1 of the inner panel PNL1 and may be a flexible structure. When the display panel PNL is in the unfolded state, the first sub-drive portion DP1 may extend along the extension direction of the inner panel PNL1. The first sub-drive portion DP1 and the display panel PNL may be an integral flexible structure, and the first sub-drive portion DP1 may also be a flexible circuit board disposed separately from the inner panel PNL1. In the deformed state, the first sub-drive portion DP1 may be bent to the non-luminous side of the inner panel PNL1.

The first sub-drive portion DP1 may be provided with a first drive chip DC1, and the first peripheral circuit of the inner panel PNL1 may be connected to the first drive chip DC1, to allow the inner panel PNL1 to display an image.

The second sub-drive portion DP2 may be connected to the second peripheral area WA2 of the outer panel PNL2 and may be a flexible structure. When the display panel PNL is in the unfolded state, the second sub-drive portion DP2 may extend along the extension direction of the inner panel PNL1. The second sub-drive portion DP2 and the display panel PNL may be an integral flexible structure, and the second sub-drive portion DP2 may also be a flexible circuit board disposed separately from the inner panel PNL1. In the deformed state, the second sub-drive portion DP2 may be bent to the non-luminous side of the outer panel PNL2.

The second sub-drive portion DP2 may be provided with a second drive chip DC2, and the second peripheral circuit of the outer panel PNL2 may be connected to the second drive chip DC2, so that the second drive chip DC2 may control the second peripheral circuit to output a drive signal, to allow the outer panel PNL2 to display an image.

As shown in FIG. 19, in some embodiments, the first sub-drive portion DP1, the second sub-drive portion DP2, and the gap GA are arranged along a straight line passing through the center of the inner panel PNL. Alternatively, the first sub-drive portion DP1, the second sub-drive portion DP2, and the gap GA may also be arranged along the circumferential direction of the inner panel PNL, and at most two of the first sub-drive portion DP1, the second sub-drive portion DP2, and the gap GA are arranged along a straight line passing through the center of the inner panel PNL.

In addition, as shown in FIG. 19, the first sub-drive portion DP1 may extend into the gap GA, making full use of the space of the gap GA to accommodate the first sub-drive portion DP1, which is beneficial for reducing the clearance between the inner panel PNL1 and the outer panel PNL2. Certainly, the first sub-drive portion DP1 and the gap GA may be spaced apart along the circumferential direction of the inner panel PNL, so that the first sub-drive portion DP1 is located between the inner panel PNL1 and the outer panel PNL2, and the clearance between the inner panel PNL1 and the outer panel PNL2 needs to be sufficient to accommodate the first sub-drive portion DP1.

In some embodiments, as shown in FIG. 20, in the deformed state, the first sub-drive portion DP1 is bent towards the non-luminous side of the inner panel PNL1, and may include a third bent portion BP3 and a third extension portion FP3. The third bent portion BP3 may connect the inner panel PNL1 with the third extension portion FP3; the third bent portion BP3 is bent towards the non-luminous side of the inner panel PNL1, and may be arc-shaped. The third extension portion FP3 may extend in the extension direction of the inner panel PNL1. Meanwhile, a gasket SG may be provided between the third extension portion FP3 and the inner panel PNL1, and the third extension portion FP3 is supported by the gasket SG. In addition, the gasket SG may be bonded to the third extension portion FP3 through an adhesive layer GL.

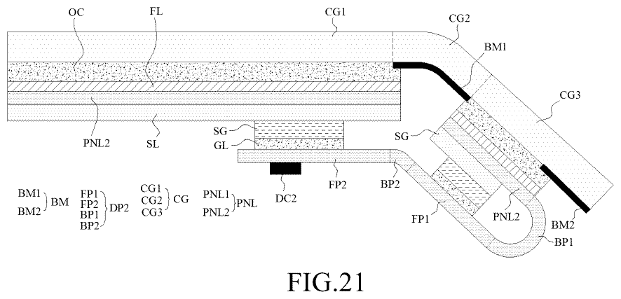

In the deformed state, as shown in FIG. 21, the second sub-drive portion DP2 is bent towards the non-luminous side of the outer panel PNL2 and includes a first bent portion BP1 and a first extension portion FP1, and the first bent portion BP1 connects the outer panel PNL2 with the first extension portion FP1. The first bent portion BP1 may be bent towards the non-luminous side of the outer panel PNL2 and may be arc-shaped, and the first extension portion FP1 extends along the extension direction of the outer panel PNL2.

As shown in FIG. 21, further, the second sub-drive portion DP2 may further include a second bent portion BP2 and a second extension portion FP2. The second bent portion BP2 connects the first extension portion FP1 with the second extension portion FP2. The second bent portion BP2 corresponds to an area between the inner panel PNL1 and the outer panel PNL2, and may be bent towards the non-luminous side of the display panel PNL. The second extension portion FP2 may extend along the extension direction of the inner panel PNL1, so that the second sub-drive portion DP2 extends to the non-luminous side of the inner panel PNL1. Meanwhile, a gasket SG may be provided between the second extension portion FP2 and the outer panel PNL2, and a gasket SG may also be provided between the second extension portion FP2 and the inner panel PNL1, so that the second sub-drive portion DP2 may be supported by the gasket SG. In addition, the gasket SG may be bonded to the second extension portion FP2 through an adhesive layer GL, and the gasket SG corresponding to the first extension portion FP1 may be bonded to the first extension portion FP1 through another adhesive layer GL.

Certainly, in other embodiments, the second sub-drive portion DP2 may not have the second bent portion BP2 and the second extension portion FP2, and the first extension portion FP1 may extend along the extension direction of the inner panel PNL1.

Based on the second embodiment described above, in some embodiments of the present disclosure, the transparent cover plate CG may have a central portion CG1 covering the inner panel PNL1, a transition portion CG2 covering an area between the inner panel PNL1 and the outer panel PNL2, and an edge portion CG3 bent towards the non-luminous side of the display panel PNL, and the specific structure may refer to the transparent cover plate CG according to the first embodiment described above, which will not be described in detail herein. In the deformed state, the first sub-drive portion DP1 is not in contact with the transition portion CG2 and the edge portion CG3, but is still covered, that is, an orthographic projection of the first sub-drive portion DP1 on a plane parallel to the central portion CG1 is within a range of an orthographic projection of the transparent cover plate CG on the plane; and the second extension portion FP2 of the second sub-drive portion DP2 may be attached to the edge portion CG3.

In some embodiments of the present disclosure, a light-absorbing layer BM may be provided between the transparent cover plate CG and the display panel PNL, and the light-absorbing layer BM may include a first light-absorbing portion BM1 and a second light-absorbing portion BM2, and may further include a third light-absorbing portion BM3 and a fourth light-absorbing portion BM4. The specific structure of the light-absorbing layer BM may refer to the light-absorbing layer BM according to the first embodiment, as long as it can cover the area between the inner panel PNL1 and the outer panel PNL2 and an edge of the outer panel PNL2, which will not be described in detail herein.

The present disclosure also provides a terminal device that may include the display apparatus according to any of the above embodiments, and the specific structure of the display apparatus may refer to the above first and second embodiments, which will not be repeated here. Meanwhile, the terminal device may further include a control main board that may be connected to the drive portion DP and configured to control, through the drive portion DP, the display panel PNL to display images. The control main board may include a processor and a memory, and the processor may include an image processing circuit that may transmit data to the drive chip DC of the drive portion DP. Certainly, the image processing circuit may also be a separate chip disposed on the control main board, which may be connected to the processor. For the second embodiment described above, the control main board may be connected to both the first sub-drive portion DP1 and the second sub-drive portion DP2.

The terminal device according to the present disclosure may be a wearable device such as a smart watch or smart glasses, and certainly, may also be other devices capable of displaying images, and application scenarios thereof are not particularly limited herein.

Other embodiments of the present disclosure will be conceived by the ordinary skilled in the art under consideration of the specification and practice of the present disclosure herein. The present disclosure is intended to cover any variations, uses, or adaptations, which follow general principles of the present disclosure and include common knowledge or the customary means in the art. The specification and embodiments are merely exemplary, and real scope and spirit of the present disclosure are indicated by the appended claims.

1. A display apparatus, comprising a display panel and a drive portion, wherein the display panel comprises:
an inner panel having a first display area and a first peripheral area located outside the first display area; and
an outer panel surrounding the inner panel and having a clearance with the inner panel, the outer panel being an annular structure having a gap, the gap cutting off the outer panel; the outer panel having a second display area and a second peripheral area located outside the second display area; and the outer panel extending towards a non-luminous side of the inner panel,
wherein the drive portion is connected to the first peripheral area and the second peripheral area, for driving the first display area and the second display area to display an image; and the drive portion is a bendable flexible structure.

2. The display apparatus according to claim 1, wherein the display panel further comprises:
a connection portion connected between the inner panel and the outer panel, the connection portion having a wiring connecting the first peripheral area and the second peripheral area, and the connection portion being a bendable flexible structure,
wherein the drive portion is connected to the second peripheral area of the outer panel, and is connected to the first peripheral area through the second peripheral area and the connection portion.

3. The display apparatus according to claim 2, wherein the drive portion, the connection portion, and the gap are arranged along a straight line passing through a center of the inner panel.

4. The display apparatus according to claim 2, wherein the drive portion, the connection portion, and the gap are arranged along a circumferential direction of the inner panel; and at most two of the drive portion, the connection portion, and the gap are arranged along a straight line passing through a center of the inner panel.

5. The display apparatus according to claim 2, wherein at least one of the connection portion and the drive portion is provided with an opening.

6. The display apparatus according to claim 5, wherein both the connection portion and the drive portion are provided with a plurality of openings;
the openings in one of the connection portion and the drive portion are divided into a plurality of opening groups arranged along a first direction; one of the opening groups comprises a plurality of the openings spaced apart along a second direction intersecting with the first direction; in adjacent opening groups, an opening of one opening group corresponds to an area between two adjacent openings of the other opening group.

7-22. (canceled)

23. The display apparatus according to claim 6, wherein a maximum dimension of the opening is not less than 0.005 mm and not greater than 2 mm.

24. The display apparatus according to claim 2, wherein the connection portion is bent towards the non-luminous side of the inner panel, and the drive portion is bent towards a non-luminous side of the outer panel and extends to the non-luminous side of the inner panel.

25. The display apparatus according to claim 24, wherein the drive portion comprises a first bent portion, a first extension portion, a second bent portion, and a second extension portion; the first bent portion connects the outer panel and the first extension portion, and the second bent portion connects the first extension portion and the second extension portion;
the first bent portion is bent towards the non-luminous side of the outer panel; the first extension portion extends along an extension direction of the outer panel; the second bent portion is bent in a same direction as the connection portion; and the second extension portion extends along an extension direction of the inner panel.

26. The display apparatus according to claim 25, wherein a gasket is provided at least one of between the second extension portion and the inner panel and between the first extension portion and the outer panel.

27. The display apparatus according to claim 2, wherein an angle between connection lines of two ends of the gap with a center of the inner panel is not greater than 30°; and/or
the gap has a width that is not greater than 8 mm.

28. The display apparatus according to claim 1, wherein the drive portion comprises a first sub-drive portion and a second sub-drive portion, which are independent of each other; the first sub-drive portion is connected to the first peripheral area; and the second sub-drive portion is connected to the second peripheral area.

29. The display apparatus according to claim 28, wherein:
the first sub-drive portion comprises a first bent portion and a first extension portion; the first bent portion connects the inner panel and the first extension portion; the first bent portion is bent towards the non-luminous side of the inner panel; and the first extension portion extends along an extension direction of the inner panel;
the second sub-drive portion comprises a second bent portion and a second extension portion; the second bent portion connects the outer panel and the second extension portion; the second bent portion is bent towards a backlight side of the outer panel; and the second extension portion extends along an extension direction of the outer panel.

30. The display apparatus according to claim 29, wherein a gasket is provided at least one of between the first extension portion and the inner panel and between the second extension portion and the outer panel.

31. The display apparatus according to claim 1, further comprising:
a transparent cover plate disposed on a light-exiting side of the display panel, the transparent cover plate comprising a central portion, a transition portion surrounding the central portion, and an edge portion surrounding the transition portion,
wherein the central portion covers the inner panel; the transition portion covers an area between the inner panel and the outer panel and is bent towards a backlight side of the display panel; and the edge portion covers the outer panel, and an edge of the outer panel is located inside an edge of the edge portion.

32. The display apparatus according to claim 31, further comprising:
a light-absorbing layer at least partially disposed between the transparent cover plate and the display panel, wherein the light-absorbing layer comprises a first light-absorbing portion and a second light-absorbing portion surrounding the first light-absorbing portion; the first light-absorbing portion covers the area between the inner panel and the outer panel; and an orthographic projection of the second light-absorbing portion on the transparent cover plate extends to a direction close to the first light-absorbing portion along an edge of the transparent cover plate.

33. The display apparatus according to claim 32, wherein the light-absorbing layer further comprises a third light-absorbing portion, and the third light-absorbing portion covers the gap.

34. The display apparatus according to claim 32, wherein the light-absorbing layer further comprises a fourth light-absorbing portion disposed on an outer peripheral surface of the transparent cover plate.

35. The display apparatus according to claim 1, wherein the display panel is a flexible structure, and the drive portion and the display panel are an integral structure.

36. A terminal device, comprising the display apparatus according to claim 1.
